(19) United States
(12) Patent Application Publication
(10) Pub. No.: US 2007/0130092 A1
(43) Pub. Date: Jun. 7, 2007

(54) Systems, Methods, and Apparatuses for Determining Demand Usage with Electricity Meters Utilized With Rolling Billing Periods

(75) Inventor: Robert E. Lee Jr., Dover, NH (US)

Correspondence Address: SUTHERLAND ASBILL & BRENNAN LLP, 999 PEACHTREE STREET, N.E., ATLANTA, GA, 30309, US

(73) Assignee: GENERAL ELECTRIC COMPANY, Schenectady, NY (US)

(21) Appl. No.: 11/164,753

(22) Filed: Dec. 5, 2005

(51) Int. Cl. G01R 21/133

(52) U.S. Cl. 705/412

(57) ABSTRACT

Systems, methods, and apparatuses are disclosed in which an electricity meter may determine demand peaks for a rolling billing period. The daily peaks for a plurality of quantities for a plurality of TOU tiers may be stored in entries in a queue. The peak demand information for a billing period may then be presented on a display or transmitted to an automatic meter reading system.

### BACKGROUND OF THE INVENTION

1. Field of the Invention

Aspects of the present invention relate generally to electricity meters, and more particularly, to systems, methods, and apparatuses for determining demand usage with electricity meters for rolling billing periods.

2. Description of Related Art

Electricity meters have been utilized by utility companies in measuring customer electricity usage for billing purposes. These electricity meters are typically viewed by the respective utility companies on a periodic basis, and the customers are then billed for their electricity usage as recorded by their electricity meters. One measure of electricity usage utilized by some utility companies for billing purposes is demand usage.

Demand usage may measure the rate at which electricity is being consumed during an interval. As electricity is consumed at a higher rate, the demand usage increases. Peak demand or maximum demand is the maximum amount of power drawn through an electricity meter during an interval a billing period. With demand usage billing, it may be necessary for the electricity meters to record the peak demand usages of customers.

Automatic meter reading (AMR) systems allow utility companies to utilize mobile vehicles or hand-held radios to read meters within a particular proximity without having to visit each meter individually. However, these meters utilized with these AMR systems may reset their recorded information periodically such that accurate peak usage within a billing period may not be captured if the meters are read early or late.

Many utility companies have already invested heavily in one-way, drive-by vehicle AMR systems for residential customers. These utility companies may now want to add customers (e.g., commercial customers) who are on a demand tariff (e.g., rate) to these one-way, drive-by vehicle AMR systems. Typical demand meters must have the peak demand reset to zero at the end of each billing period. For instance, utility companies typically dispatched personnel to read the demand information (e.g., kWh and maximum kW) and subsequently press the demand reset button. This requires the utility company to interact with the meters directly. Such interaction presents various difficulties and extra costs for a utility company's one-way, drive-by vehicle AMR systems. These one-way AMR systems may not be able to interact with the meters to reset the demand information.

Other electricity meters for use with one-way, drive-by vehicle AMR systems have included a calendar with programmed reset dates. These meters may automatically perform an automatic demand reset on those reset dates. Thus, the demand information (e.g., kWh and kW) information in the meters must be read by the one-way AMR systems prior to the scheduled automatic demand reset on those read dates. If the meters are read late, then the demand information (e.g., kWh and kW information) may be lost. Alternative meters may transmit previous demand information (e.g., kWh and kW) after the reset dates. In this situation, the meters must be read by the one-way AMR systems after the reset dates. They cannot be read prior to the reset dates. In both of these cases, a utility company may have much difficulty in moving a customer to a different reading schedule. For example, the utility company may have to program a new calendar with reset dates for the customer.

Accordingly, there is a need in the industry for electricity meters utilizing flexible billing periods for use with AMR systems that can accurately provide peak demand usages without necessarily requiring two-way communications with the meters or requiring a calendar with the read schedule to be stored in the meters.

### BRIEF DESCRIPTION OF THE INVENTION

According to an embodiment, there is disclosed a method for determining demand data in an electricity meter. The method includes providing a queue having a plurality of entries, determining at least one demand peak for a current time period, storing the demand peak in a first entry in the queue, at an end of the current time period, initializing a second entry in the queue for storing a peak demand for another time period subsequent to the current time period, where the second entry overwrites an oldest entry in the queue, identifying within the plurality of entries of the queue at least one demand peak in a billing period, and storing in a memory the identified at least one demand peak in the billing period.

According to an aspect of the invention, providing a queue includes providing a queue having the plurality of entries based upon a number of business days in the billing period. The queue may be a circular queue. According to another aspect of the invention, determining at least one demand peak includes determining demand peaks for a plurality of intervals for the current time period. According to yet another aspect of the invention, the method further includes presenting on a display one or more of the identified at least one demand peak. According to still another aspect of the invention, the method further includes transmitting one or more of the identified at least one demand peak to an automatic meter reading system. According to another aspect of the invention, storing the identified at least one demand peak in the billing period includes storing an indication of a date in association with the identified at least one demand peak.

According to another embodiment of the invention, there is disclosed an electricity meter apparatus. The electricity meter apparatus includes a memory, one or more sensors for providing demand information, and a processor in communication with the memory, wherein the memory includes executable instructions for determining at least one demand peak from demand information for a current time period, storing the demand peak in a first entry in a queue having a plurality of entries, at an end of the current time period, initializing a second entry in the queue for storing a peak demand for another time period subsequent to the current time period, where the second entry overwrites an oldest entry in the queue, and locating within a plurality of entries of the queue at least one demand peak in a billing period.

According to an aspect of the invention, the queue may be a circular queue. According to another aspect of the invention, determining at least one demand peak from demand information includes determining at least one demand peak associated with a time of use (TOU) tier during the current time period. According to yet another aspect of the invention, the electricity meter apparatus further includes a display for indicating the at least one demand peak in the billing period. According to another aspect of the invention, the electricity meter apparatus further includes a communications module operable for transmitting the at least one demand peak in the billing period. The communications module may be operable for communicating with an automatic meter reading system.

According to another embodiment of the invention, there is disclosed an electricity distribution system. The electricity distribution system includes a plurality of customer lines for receiving electricity from a utility company, at least one electricity meter coupled to each customer line, where each electricity meter includes one or more sensors for providing demand information, a processor in communication with at least one sensor that determines at least one demand peak from demand information for a current time period, a queue in communication with the processor and having a plurality of entries for storing the demand peak in a first entry, means for initializing a second entry in the queue for storing a peak demand for another time period subsequent to the current time period, where the second entry overwrites an oldest entry in the queue, and means for locating within the entries of the queue at least one demand peak in a billing period. The electricity distribution system further includes a communications system that provides communications between the electricity meters and the utility company.

According to an aspect of the invention, the queue may be a circular queue. According to another aspect of the invention, the electricity meter further includes a communications module for operation with the communications system. The communications module may be operable for transmitting an indication of at least one demand peak to a mobile vehicle of an automatic meter reading system. According to another aspect of the invention, the electricity meter further includes a display for indicating at least one demand peak. According to yet another aspect of the invention, determining at least one demand peak from demand information includes determining at least one demand peak associated with a time of use (TOU) tier. According to yet another aspect of the invention, the demand information includes information associated with one or more of rolling demand, block demand, and thermal emulation.

### BRIEF DESCRIPTION OF THE DRAWINGS

Having thus described aspects of the invention in general terms, reference will now be made to the accompanying drawings, which are not necessarily drawn to scale, and wherein:

FIG. 1 illustrates an exemplary system overview diagram according to an embodiment of the present invention.

FIG. 2 illustrates an exemplary block diagram of an electricity meter according to an embodiment of the present invention.

FIG. 3 illustrates an exemplary circular queue according to an embodiment of the present invention.

FIG. 4 is an illustrative flowchart of demand interval processing in an exemplary meter according to an embodiment of the present invention.

FIG. 5 is an illustrative flowchart of daily processing in an exemplary meter according to an embodiment of the present invention.

### DETAILED DESCRIPTION OF THE INVENTION

The present invention is described below with reference to figures and flowchart illustrations of systems, methods, apparatuses and computer program products according to an embodiment of the invention. It will be understood that each block of the flowchart illustrations, and combinations of blocks in the flowchart illustrations, respectively, may be implemented by computer program instructions. These computer program instructions may be loaded onto a general purpose computer, special purpose computer, or other programmable data processing apparatus to produce a machine, such that the instructions which execute on the computer or other programmable data processing apparatus create means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including instruction means that implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

Accordingly, blocks of the flowchart illustrations support combinations of means for performing the specified functions, combinations of steps for performing the specified functions and program instruction means for performing the specified functions. It will also be understood that each block of the flowchart illustrations, and combinations of blocks in the flowchart illustrations, can be implemented by special purpose hardware-based computer systems that perform the specified functions or steps, or combinations of special purpose hardware and computer instructions. The inventions may be implemented through an application program running on an operating system of a computer. The inventions also may be practiced with other computer system configurations, including hand-held devices, multiprocessor systems, microprocessor based or programmable consumer electronics, mini-computers, mainframe computers, etc.

Application programs that are components of the invention may include routines, programs, components, data structures, etc. that implements certain abstract data types, perform certain tasks, actions, or tasks. In a distributed computing environment, the application program (in whole or in part) may be located in local memory, or in other storage. In addition, or in the alternative, the application program (in whole or in part) may be located in remote memory or in storage to allow for the practice of the inventions where tasks are performed by remote processing devices linked through a communications network.

The present invention will now be described more fully hereinafter with reference to the accompanying figures, in which like numerals indicate like elements throughout the several drawings. Some, but not all embodiments of the invention are described. Indeed, these inventions may be embodied in many different forms and should not be construed as limited to the embodiments set forth herein; rather, these embodiments are provided so that this disclosure will satisfy applicable legal requirements, be thorough and complete, and will fully convey the scope of the invention to those skilled in the art.

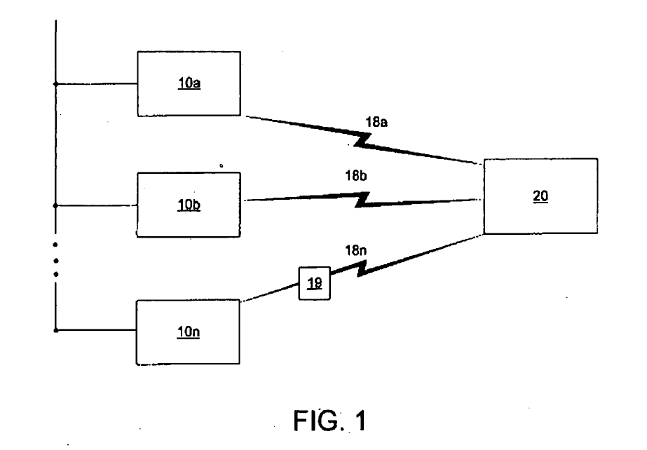

FIG. 1 illustrates an exemplary system overview diagram according to an embodiment of the present invention. Referring to FIG. 1, an electricity meter 10a . . . 10n, may be provided to each of a plurality of customer lines from which electricity may be received from a utility company 20. The meters 10a . . . 10n may monitor and store electricity usage and/or demand information for the plurality of customer lines. The meters 10a . . . 10n may further monitor and record status information for the plurality of customer lines. The utility company 20 may interact with the meters 10a . . . 10n through respective signal paths 18a . . . 18n of a communication system to retrieve information from the meters 10a . . . 10n. A variety of methods, both wired and wireless, may be utilized for the signal paths 18a . . . 18n of the communications system according to an embodiment of the present invention. For example, the electricity meters 10a . . . 10n may communicate through a telephone line, an automatic meter reading system 19, an optical port, an RS-232 line, wireless systems, and many other means of communications. In addition, receiving devices, such as hand-held devices may communicate with the electricity meters 10a . . . 10n. The receiving devices may then subsequently communicate any collected information to the utility company 20. The receiving devices may include cellular devices such as phones, PDAs, notebook computers, specialized receivers, or handheld devices. The receiving devices or aspects thereof may also be incorporated with mobile vehicles, including those utilized with automatic meter reading systems 19. The mobile vehicles may include vans, cars, ATVs, motorcycles, segways, planes, remote control planes, and a variety of other transportation vehicles. According to an illustrative embodiment, a drive-by vehicle such as a van may be utilized with an automatic meter reading system 19. Many other variations are well-known to one of ordinary skill in the art.

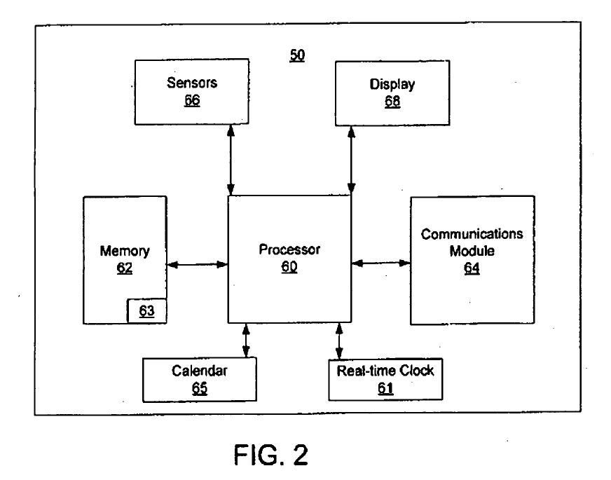

FIG. 2 illustrates an exemplary electricity meter 50 according to an embodiment of the present invention. The meter 50 may be coupled to an alternating current (AC) power source provided by the utility company. The meter 50 includes a processor 60, a memory 62, a communications module 64, one or more sensors 66, and a display 68. According to one embodiment, processor 60 may be a microprocessor with read-only memory (ROM) and/or random access memory (RAM). For example, processor 60 may be a 32 bit microcomputer with 2 Mbit ROM, 64 Kbit RAM. The processor 60 may also be in communications with a real-time clock 61 and a calendar 65, both of which may be discrete components or implemented as software in the memory 62. The memory 62 may include a variety of storage methods, including flash memory, electronically erasable programmable memory, read only memory (ROM), removable media, and other volatile and non-volatile storage devices as are understood by one of ordinary skill in the art. The memory 62 may be utilized in implementing a queue, including a circular queue, as will be discussed below. One of ordinary skill in the art will appreciate that the memory 62 may include a plurality of memories and memory modules.

Still referring to FIG. 2, the processor 60 may execute instructions 63 (e.g., software instructions) stored in the memory 62 and may also store data in the memory 62. The communications module 64 may be utilized for transmitting information to and perhaps for receiving information from the utility company. For example, the communications module 64 may include one or more of optical ports for communicating with an external reader, a telephone modem, an RS-232 line, a simple input/output (I/O) board, a complex I/O board, and a plurality of wireless and cellular technologies as understood by one of ordinary skill in the art. In addition, the communications module 64 may communicate with an automatic meter reading system, which may include a drive-by vehicle for communicating with the meter 50. The sensors 66 may include current and voltage sensors and may generate measurements of current and voltage. The sensors 66 may also provide demand information or other information utilized in determining demand information. Further the sensors 66 may include or be in communication with analog-to-digital converters and/or digital signal processors. The display 68 may be utilized to display a plurality of information associated with the meter, including electricity usage and demand along with status alerts. The display 68 may be of virtually any display technology, including LCD, plasma, CRT, and analog-type displays. In addition, although not shown, the meter 50 may include a power source such as a battery. Implementations of meters 50 in accordance with embodiments of the present invention may be include other components as desired for the operation of a meter, such as are generally described in U.S. Pat. No. 6,778,920.

Embodiments of the present invention may include electricity meters 50 with real-time clocks 61, calendars 65, and queues in memory 62 for recording daily peak demand data (also referred to as “demand quantities”) for enough calendar days to cover the maximum number of business days in a billing period. One of ordinary skill in the art will recognize that the time periods (e.g., daily) may be varied according in accordance with embodiments of the invention. A billing period may include the time between two consecutive meter readings, sometimes around 30 or 31 calendar days. The number of calendar days within a billing period may vary according to several factors, including holiday schedules and the ability of utility companies to dispatch meter readers on a timely basis. Because the maximum number of business days in a billing period excludes weekends and holidays, the total number of calendar days that may be supported by the queue may exceed the maximum number of business days in the billing period. These holidays may be programmed by the utility company in the calendar 65.

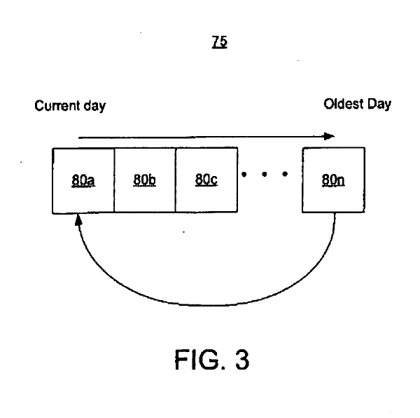

According to an embodiment of the invention, referring to FIG. 3, the queue 75, which is a circular queue in the illustrative embodiment, may include a plurality of locations or entries 80a-n (e.g., records) within the memory 62 located within the meter 50. However, it will be understood that the queue 75 may generally include any array or plurality of memory locations or memory modules for storing information. One or more memory locations or entries 80a-n may be provided for a particular time period (e.g., day) such that there are sufficient numbers of memory locations or entries 80a-n to support a plurality of time periods (e.g., days). According to an aspect of the invention, the circular queue 75 may operate sequentially, such that a memory location or entry 80a-n corresponding to a previous or oldest entry may be overwritten by data for a current entry. For example, memory location or entry 80a may be associated with a current day while memory location 80n may be associated with an oldest previous day. Accordingly, the memory location or entry 80a-n for a current day shifts in a cycle as data is stored from one day to the next based on the number of days supported by the circular queue 75 (e.g., the number of locations or entries 80a-n). In other words, at some point in the cycle, a memory location or entry 80a-n associated with a previous day will be overwritten by an entry for a current day. The total number of calendar days that may be supported by the circular queue 75 will next be described.

According to one embodiment of the invention, the circular queue 75 covers 24 business days and records daily peak demand data for all quantities for all TOU tiers for 38 calendar days. According to another embodiment of the invention, the circular queue 75 covers 21 business days and records daily peak demand data for all quantities for all TOU tiers for 34 calendar days. The queue 75 may be circular in that peak demand data for a current day may be recorded over older peak demand data for a previous day. One of ordinary skill in the art will recognize that other queues 75 may cover more or less business days than 21 or 24 business days and the number of calendar days recorded by the queue 75 would be adjusted accordingly.

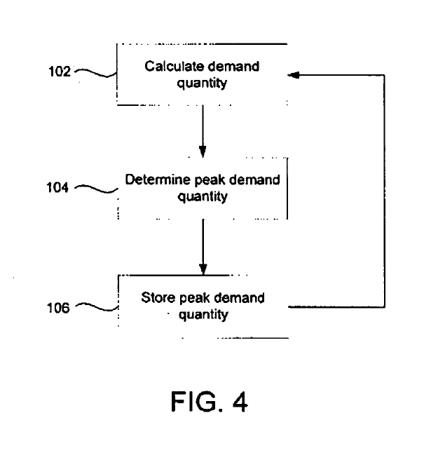

According to an aspect of the present invention, as illustrated in FIG. 4, each of these daily records of the circular queue 75 is capable of recording peak demand data for each demand quantity (e.g., kW, kVar, kVA, etc.) for each active time-of-use (TOU) tier. Generally, only one TOU tier may be active, although in other embodiments, there may be no TOU tiers. Referring to FIG. 4, these peak demand quantities are determined by the meter 50 on a periodic interval during a time period (e.g., a day) during which a TOU tier may be active (block 102). At the end of each demand interval, the meter 50 determines the demand for each quantity (e.g., kW, kVar, kVA, etc.) for the TOU tier (block 104), perhaps using for example, thermal emulation, block, rolling, etc. The peak demands that are calculated for each quantity during a TOU tier may be compared to the overall totals for determining an overall peak and a TOU tier peak. The meter 50 keeps track of the peak demand for each quantity for each TOU tier (as well as an overall peak demand) for this day in a memory 62 (block 106). This process may repeat for each interval during the time period (e.g., day) in the illustrative embodiment.

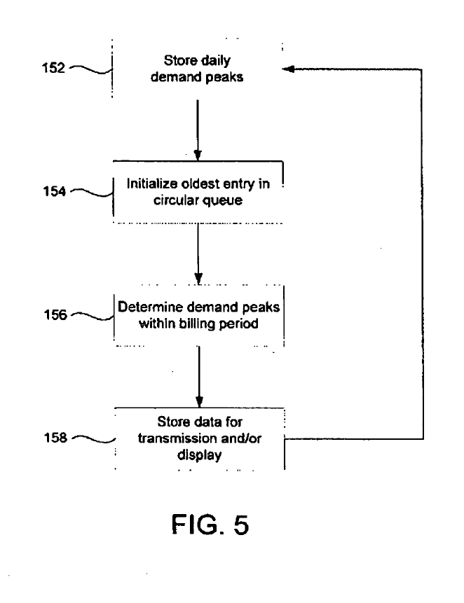

Referring now to FIG. 5, according to an illustrative embodiment, at the end of each day, the meter 50 stores the daily peak demand for each quantity in one entry of the circular queue 75 already designated for that day (block 152). The meter 50 then initializes the oldest entry in the circular queue 75 for use for the current day (block 154). The meter 50 then applies the appropriate rolling period algorithm to a plurality of entries 80a-80n in the circular queue 75 to determine the billing period peaks (block 156). The meter 50 then stores the resulting demand peaks for either presentation by display 68 and/or transmission by the communications module 64 of the meter 50 to a receiver or an AMR system 19 (block 158). The process repeats for each day in the illustrative embodiment.

The algorithm utilized in the determination of the billing period peaks of FIG. 2 may depend on the characteristics of the AMR system 19 and the preferences of the electric utility company. Some of these characteristics and preferences may include the available bandwidth of the meter 50, the type of communication network the meter includes, the frequency that the meters 50 are read, and the utility company's tolerance for estimated bills and for potentially-lost peaks.

In particular, the bandwidth available affects the number of peak quantities that can be transmitted to the AMR system 19. If the meter 50/AMR system 19 has a very high bandwidth, then all of the entries in the queue 75 may be transmitted by the communications module 64 of the meter to the AMR system 19 along with a date stamp. The AMR system 19 then provides the utility company's billing system with the transmitted entries such that the billing system can determine the appropriate peak demand quantities to use during the billing period. On the other hand, if meter 50/AMR system 19 has a very limited bandwidth capable of only transmitting a single peak quantity with no date stamp, then the peak quantity with the highest probability of being in the actual billing period may be selected for transmission.

The type of network and frequency of reads may be related. With many AMR systems 19, the meters 50 may only be read on a monthly basis. Thus, during each monthly read, the meters 50 may transmit the peak quantities with the highest probability of being in the actual billing period.

In addition, the algorithm may be tailored in accordance with the present invention to the utility company's preferences for estimated bills and lost peaks. To reduce the probability of an estimated bill, peaks with highest probability of being in the actual billing period are selected. Accordingly, fewer business days (e.g., 18 business days or less) may be included for more conservative utility companies that desire fewer estimated bills. On the other hand, for utility companies that want to avoid missing the highest peak in the billing period, peak quantities with the highest peak out to the maximum range are selected. Thus, these less-conservative utility companies may desire to include more business days (e.g., 24 business days or more) to reduce the number of lost peaks, but at the risk of including peaks outside of the billing period.

In formulating an appropriate algorithm(s), the different approaches may be combined. If more than one peak quantity can be transmitted, different algorithms may be applied to each peak quantity.

In order for the utility company to determine if the peak demand is within the actual billing period, the meter 50 must provide the AMR system 19 with enough data to make this determination. This data can be provided in several ways including through a peak and date stamp, a peak and date offset, or a peak and implied offset.

With a peak and date stamp method, the meter 50 would return one or more peak quantities along with the date that each peak quantity occurred on. The time could also be included, but is not necessary for billing purposes. The billing system would utilize date information to filter out peaks that happened before the previous meter 50 read date (i.e., during the last billing period).

A peak and date offset method is similar to the peak and date method above, except an offset is transmitted with the peak quantity. The offset could be referenced in days. According to one embodiment of the invention, the offset could be in business days. According to another embodiment of the invention, the offset could be in calendar days. The date that the peak quantity occurred may be calculated by using the offset with the meter 50 read date (e.g., meter read date minus offset). Once the date of the peak quantity has been determined, the billing system can filter out peak quantities that may have occurred before the previous meter 50 read date.

With a peak plus implied offset method, no date stamp is transmitted by the meter with the peak quantity. Instead the peak quantity may be within a fixed number of business days (i.e., the implied offset) from the meter 50 read date. The worst-case date may be determined from the meter 50 read date and the implied offset. The billing system may use the worst-case date to filter out peak quantities that may have occurred before the previous meter 50 read date.

With each of the methods discussed above, if the peak quantity happened before the previous meter 50 read date (i.e., beginning of the billing period), it must be excluded for billing purposes. If no other peak that is within the billing period is available when the customer's bill is produced, then the bill must be estimated.

Exemplary algorithm for unlimited bandwidth with no date stamp

In this exemplary embodiment, the meter 50/AMR system 19 includes a very high bandwidth or an unlimited bandwidth. Thus, the AMR system 19 is capable of retrieving all peaks for multiple quantities (e.g., kW, kVar, kVA, etc.) for multiple TOU tiers. The utility company may have an average of 21 business days between scheduled meter reads. Meters 50 may be read within a four business day window from one business day before the scheduled meter 50 read date to two business days after the scheduled meter 50 read date.

Assuming the four business day meter reading window, the actual billing period can have a range of 18 to 24 business days. Thus, the minimum number of business days within the billing period would be 18 business days. The maximum number of business days in the billing period would be 24 days. With 24 business days, the maximum number of calendar days would be 38 days. In the worst case, there may be as many as seven possible peaks, one for each of the possible range of 18 to 24 business day billing periods. Since there is no limit on bandwidth, all seven peaks, for all billing quantities, for all TOU tiers may be calculated and returned:

Peak 1: 18 business days

Peak 2: 19 business days

Peak 3: 20 business days

Peak 4: 21 business days

Peak 5: 22 business days

Peak 6: 23 business days

Peak 7: 24 business days

According to an aspect of the exemplary algorithm, the meter 50 would first reset at all peaks for all quantities for all totals and TOU tiers. The meter 50 would then look back 18 business days from the current day and store the peaks for all quantities for all TOU tiers as Peak 1. This would be repeated for any additional peak quantities, totals, and TOU tiers. The meter 50 would then repeat this process for 19-24 business days from the current day for Peaks 2-7, respectively. Peaks 1-7 would then be transmitted from the meter 50 as may be required by the AMR system 19.

Exemplary algorithm for limited bandwidth, no date stamp, and a low tolerance for estimated bills.

In this exemplary embodiment, the algorithm is optimized for a limited bandwidth, drive-by AMR system 19. The AMR system 19 is capable of retrieving 2 peaks for a single quantity (e.g., kW). The utility company may have an average of 21 business days between scheduled meter 50 reads. Meters 50 must be read within a four business day window from one business day before the scheduled meter 50 read to two business days after the scheduled meter 50 read.

Assuming the four business day meter reading window, the actual billing period can have a range of 18 to 24 business days. Because only 2 peaks for a single quantity can be transmitted, the algorithm will select two of the range of 18 to 24 business days. According to one embodiment of the present invention the algorithm will the algorithm will look back 18 business days for the first peak quantity. This peak quantity is guaranteed to be within the billing period assuming that the criteria for four business day reading window has not been violated. In addition, the algorithm will look back 21 business days for the second peak quantity. This second peak quantity will give the utility company another opportunity to capture a higher peak quantity with a high probability that it is within the billing period. The minimum number of days with the billing period would be 18 business days. The maximum number of business days within the billing period would be 21 business days. With 21 business days, the maximum number of calendar days would be 34 days. The two peak quantities are shown below:

Peak 1: Minimum Billing Period=18 business days

Peak 2: Average Billing Period=21 business days

If the meter 50 is read late, there is a potential that the actual peak for the billing period may fall off the end of the 21 business day horizon. However, because of the utility company's low tolerance for estimated bills, it is more desirable to have a peak quantity that can be used for billing, thereby avoiding estimated bills and ensuing customer service issues, than to get the absolute maximum peak quantity, which may result in a loss of revenue.

According to an aspect of the exemplary algorithm, the meter 50 would reset all peak quantities. The meter 50 would then look back 18 business days and store the peak for all quantities for all TOU tiers as Peak 1. The meter 50 would then look back 21 business days and store the peak quantity as Peak 2. The two peak quantities are then transmitted from the meter 50 as required by the AMR system 19.

Exemplary algorithm for limited bandwidth with date stamp and a low tolerance for estimated bills

According to an exemplary embodiment, this algorithm is similar to the one above, except that the AMR system 19 is capable of retrieving 2 peaks for a single quantity (e.g., kW), each of which includes a date stamp, either based on an absolute calendar date or an offset. By including the date stamp, the billing system can reject peak quantities that are not within the billing period, and the meter 50 can look beyond the average billing period of 21 days for additional peaks. According to an aspect of the exemplary algorithm, the algorithm will look back 18 business days for the first peak quantity. This peak quantity is guaranteed to be within the billing period assuming that the criteria for reading the meter 50 within the four business day window has not been violated. The exemplary algorithm will continue to look out at least 21 business days until it finds a new peak quantity or otherwise reaches 24 business days for the second peak quantity. With 24 business days, the maximum number of calendar days within the billing period would be 34 days. By allowing the exemplary algorithm to search beyond 21 business days if no peak greater than the 18 business day peak is found, this algorithm may find peaks that might otherwise have dropped off the end when the meter 50 is read late. The two peak quantities are shown below:

Peak 1: Minimum Billing Period=18 business days

Peak 2: Average Billing Period=21 business days

According to an aspect of the exemplary algorithm, the meter 50 would reset all peaks for all quantities for all TOU tiers. The meter would then look back 18 business days and store the peak and date stamp for all quantities for all TOU tiers as Peak 1. The meter would then look back 21 business days. If a new peak has been found, the peak and date stamp for all quantities for all TOU tiers would be stored as Peak 2. However, in no new peak has been located, the meter 50 continues out to 24 business days or until a new peak quantity is found. The peak and date stamp for all quantities for all TOU tiers is stored as Peak 2. The two peaks and date stamps for all quantities and TOU tiers and are then transmitted as required by the AMR system 19.

One of ordinary skill in the art will recognize that the peaks for all quantities for all TOU tiers may be implemented in a variety of ways. According to one embodiment, the meter 50 may decide the number of peaks for each quantity for each TOU tier to store in the queue 75. The meter 50 may also to decide to store dates or date offsets. However, according to another embodiment, the meter 50 could store all peaks for all quantities for all TOU tiers in the queue 75. Dates and date offsets may also be stored. In this situation, the communications module 64 may decide how many peaks to transmit (with or without dates) to the AMR system 19.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A method for determining demand data in an electricity meter, comprising:
providing a queue having a plurality of entries;
determining at least one demand peak for a current time period;
storing the demand peak in a first entry in the queue;
at an end of the current time period, initializing a second entry in the queue for storing a peak demand for another time period subsequent to the current time period, wherein the second entry overwrites an oldest entry in the queue;
identifying within the plurality of entries of the queue at least one demand peak in a billing period; and
storing in a memory the identified at least one demand peak in the billing period.

2. The method of claim 1, wherein providing a queue comprises providing a queue having the plurality of entries based upon a number of business days in the billing period.

3. The method of claim 1, wherein the queue comprises a circular queue.

4. The method of claim 1, wherein determining at least one demand peak comprises determining demand peaks for a plurality of intervals for the current time period.

5. The method of claim 1, further comprising presenting on a display one or more of the identified at least one demand peak.

6. The method of claim 1, further comprising transmitting one or more of the identified at least one demand peak to an automatic meter reading system.

7. The method of claim 1, wherein storing the identified at least one demand peak in the billing period comprises storing an indication of a date in association with the identified at least one demand peak.

8. An electricity meter apparatus, comprising:
a memory;
one or more sensors for providing demand information; and
a processor in communication with the memory, wherein the memory comprises executable instructions for:
determining at least one demand peak from demand information for a current time period;
storing the demand peak in a first entry in a queue having a plurality of entries;
at an end of the current time period, initializing a second entry in the queue for storing a peak demand for another time period subsequent to the current time period, wherein the second entry overwrites an oldest entry in the queue; and
locating within a plurality of entries of the queue at least one demand peak in a billing period.

9. The electricity meter apparatus of claim 8, wherein the queue comprises a circular queue.

10. The electricity meter apparatus of claim 8, wherein the determining at least one demand peak from demand information comprises determining at least one demand peak associated with a time of use (TOU) tier during the current time period.

11. The electricity meter apparatus of claim 8, further comprising a display for indicating the at least one demand peak in the billing period.

12. The electricity meter apparatus of claim 8, further comprising a communications module operable for transmitting the at least one demand peak in the billing period.

13. The electricity meter apparatus of claim 12, wherein the communications module is operable for communicating with an automatic meter reading system.

14. An electricity distribution system comprising:
a plurality of customer lines for receiving electricity from a utility company;
at least one electricity meter coupled to each customer line, wherein each electricity meter comprises:
one or more sensors for providing demand information;
a processor in communication with at least one sensor that determines at least one demand peak from demand information for a current time period;
a queue in communication with the processor and having a plurality of entries for storing the demand peak in a first entry;
means for initializing a second entry in the queue for storing a peak demand for another time period subsequent to the current time period, wherein the second entry overwrites an oldest entry in the queue; and
means for locating within the entries of the queue at least one demand peak in a billing period; and
a communications system that provides communications between the electricity meters and the utility company.

15. The system of claim 14, wherein the queue is a circular queue.

16. The system of claim 14, wherein the electricity meter further comprises a communications module for operation with the communications system.

17. The system of claim 16, wherein the communications module is operable for transmitting an indication of at least one demand peak to a mobile vehicle of an automatic meter reading system.

18. The system of claim 14, wherein the electricity meter further comprises a display for indicating at least one demand peak.

19. The system of claim 14, wherein determining at least one demand peak from demand information comprises determining at least one demand peak associated with a time of use (TOU) tier.

20. The system of claim 14, wherein the demand information comprises information associated with one or more of rolling demand, block demand, and thermal emulation.
